(19) United States
(12) Patent Application Publication
(10) Pub. No.: US 2017/0261376 A1
(43) Pub. Date: Sep. 14, 2017

(54) Method of Making a Variable Emittance Window

(71) Applicant: The Government of the United States of America, as represented by the Secretary of the Navy, Arlington, VA (US)

(72) Inventors: Virginia D. Wheeler, Alexandria, VA (US); Francis J. Kub, Arnold, MD (US); Charles R. Eddy, JR., Columbia, MD (US); Marko J. Tadjer, Springfield, VA (US)

(73) Assignee: The Government of the United States of America, as represented by the Secretary of the Navy, Arlington, VA (US)

(21) Appl. No.: 15/606,575

(22) Filed: May 26, 2017

Related U.S. Application Data
(62) Division of application No. 14/731,235, filed on Jun. 4, 2015.
Application No. 14/731,235 is a continuation of application No. 14/729,441, filed on Jun. 3, 2015.
(60) Provisional application No. 62/012,600, filed on Jun. 16, 2014.

(51) Int. Cl. G01J 5/20; G02B 1/14; G02F 1/01; C23C 16/455; G02B 1/11; G01J 5/08; G02B 1/18

(52) U.S. Cl. CPC G01J 5/20; G01J 5/0853; G02B 1/14; G02B 1/18; Y10T 156/10; C23C 16/45525; G02B 1/11; G02F 1/0147; G02B 1/10

(57) ABSTRACT

A method of making a variable emittance window comprising providing a metal foil substrate, applying an antireflection material layer onto the metal foil substrate, applying a protection material layer onto the antireflection material layer, applying a variable emittance material layer onto the protection material layer, annealing to form a two-step variable emittance layer, applying a transparent low emittance material layer to the two-step variable emittance layer, adhering a transparent substrate to the transparent low emittance material layer, and removing the metal foil substrate.

### REFERENCE TO RELATED APPLICATION

This application claims priority to and the benefits of U.S. Patent Application No. 62/012,600 filed on Jun. 16, 2014, U.S. patent application Ser. No. 14/731,235 filed on Jun. 5, 2015, and U.S. patent application Ser. No. 14/729,441 filed on Jun. 5, 2015, the entirety of each is herein incorporated by reference.

### BACKGROUND

This disclosure generally concerns a variable emittance window device.

The typical or prior art deposition temperature for physical vapor deposited vanadium oxide with significant VO₂ bonding content is 500° C.

As used in the present disclosure, thermochromic material layer means that the material layer has an emittance value that varies with the temperature of the device structure material.

For example, devices can be smart window devices or infrared detector devices.

Here, deposition can occur at a temperature of below or about 115° C.

### BRIEF SUMMARY OF THE INVENTION

This disclosure describes devices that use low temperature deposited atomic layer deposition vanadium oxide, deposited at a temperature of about or below 115° C., and a method of making.

For example, devices can be smart window devices.

### BRIEF DESCRIPTION OF THE DRAWINGS

FIG. 1 illustrates XPS spectra taken after different ion sputtering times. The top surface of the film corresponds to 0 s. The initial surface shows components of both V₂O₅ and VO₂ while nearer the substrate interface (28 s) shows the presence of an oxygen deficient component.

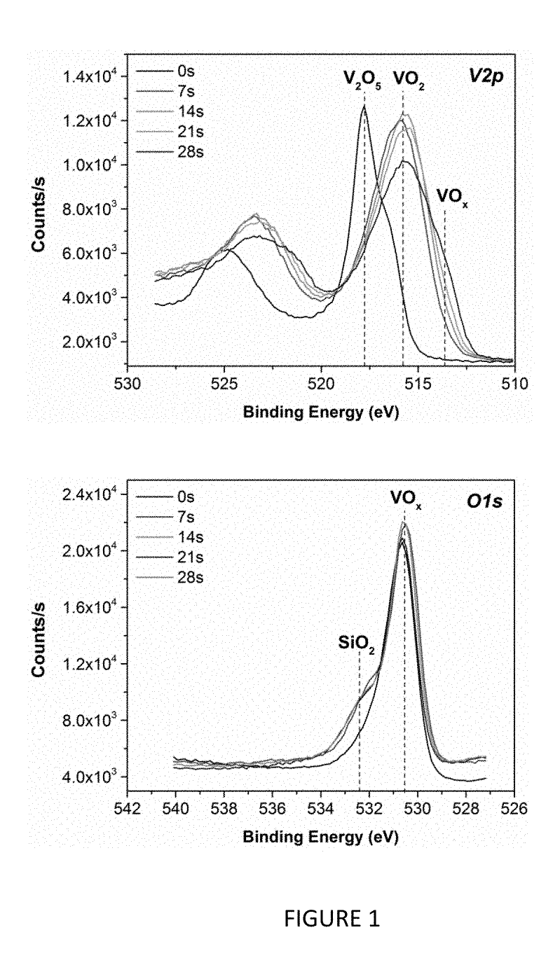

FIG. 2 illustrates electrical properties as a function of temperature of 7, 15, and 34 nm thick films grown on substrates of Si (open symbols) and sapphire (filled symbols). The amorphous films exhibit a nine order of magnitude change in resistance over the 77-500K temperature range.

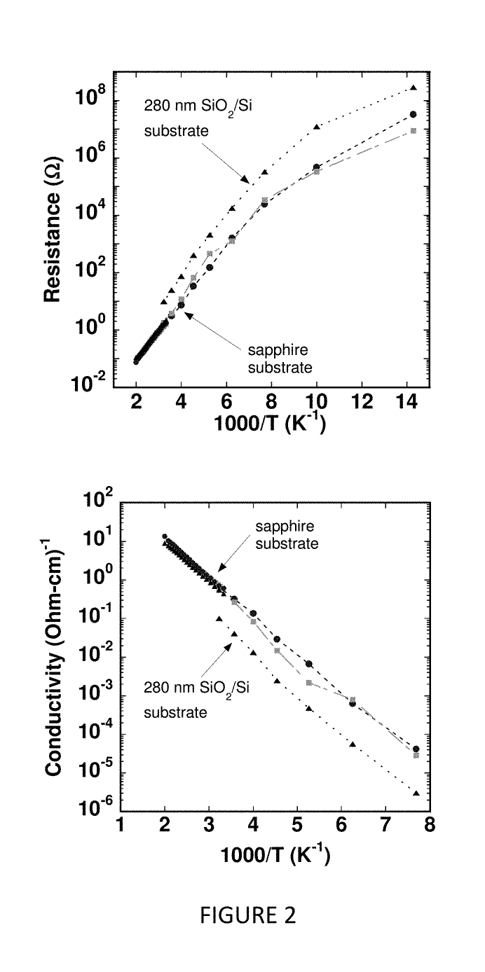

FIG. 3 illustrates a variable emittance material layer on a transparent substrate for a smart window.

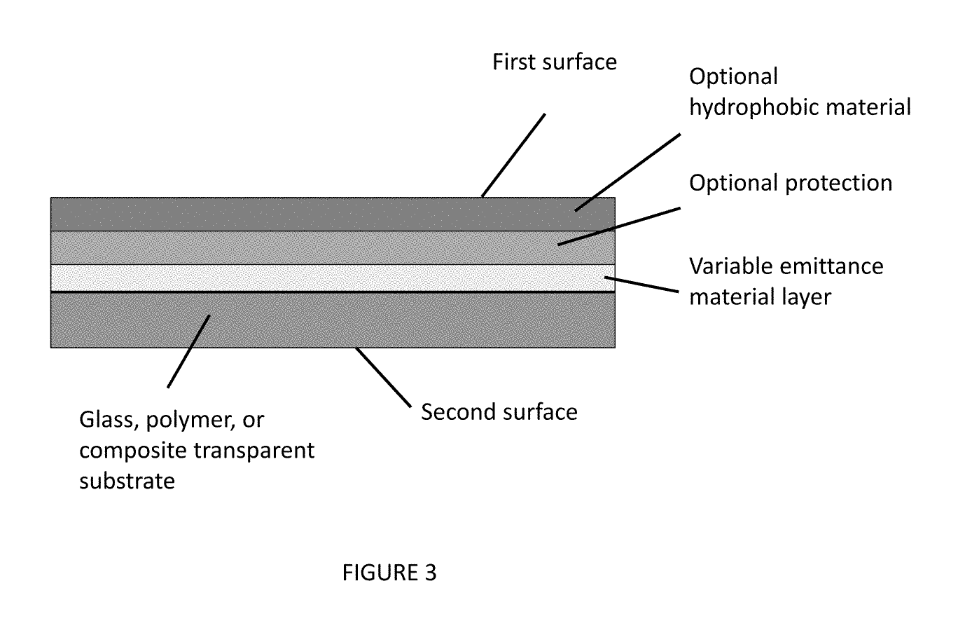

FIG. 4 illustrates a vanadium oxide coating on transparent conducting oxide, for example fluorine doped tin oxide or antimony oxide, on a substrate for a smart window.

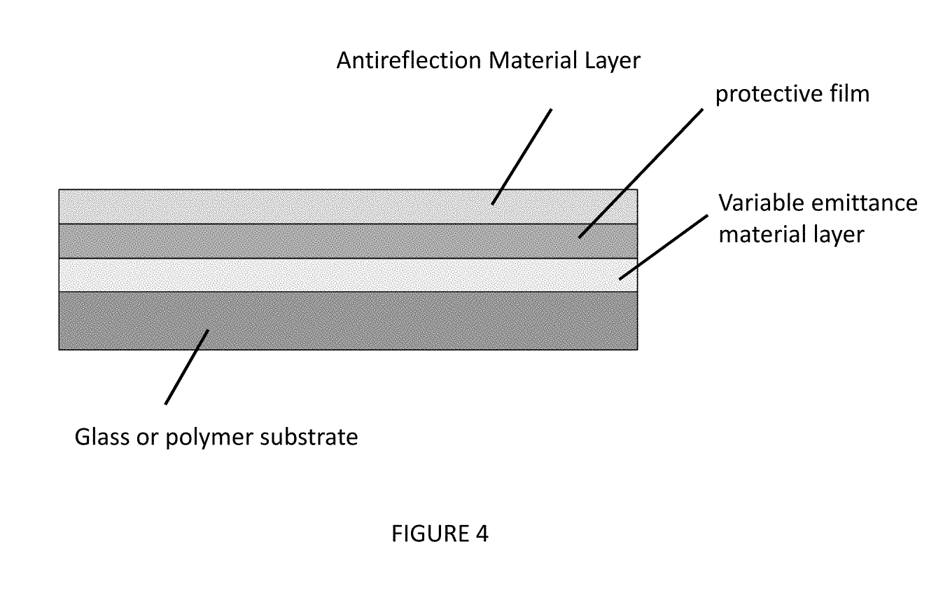

FIG. 5 illustrates a vanadium oxide coating on transparent conducting oxide, for example fluorine doped tin oxide or antimony oxide, on a substrate for a smart window.

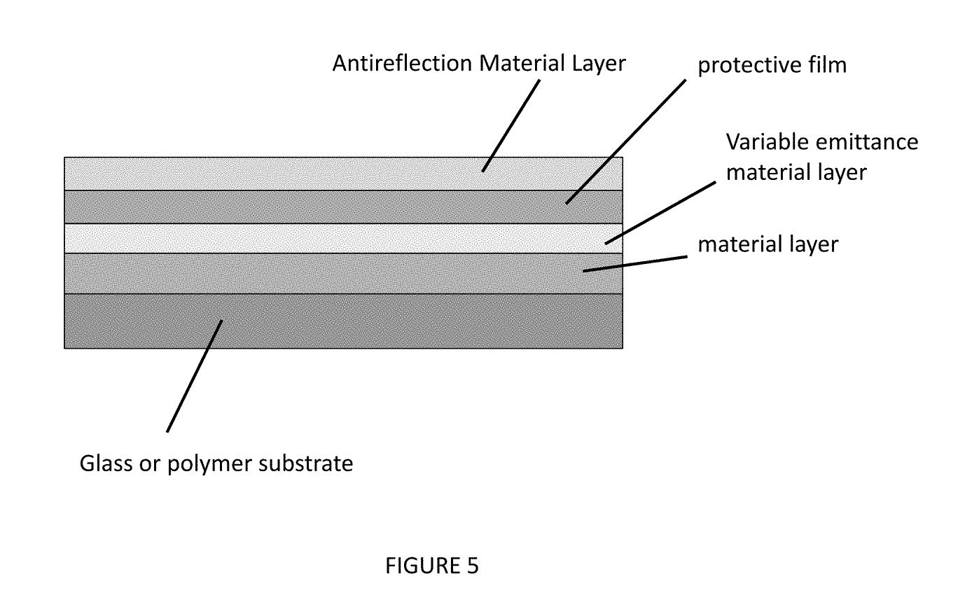

FIG. 6 illustrates a vanadium oxide coating on transparent conducting oxide, for example fluorine doped tin oxide or antimony oxide, on a substrate for a smart window.

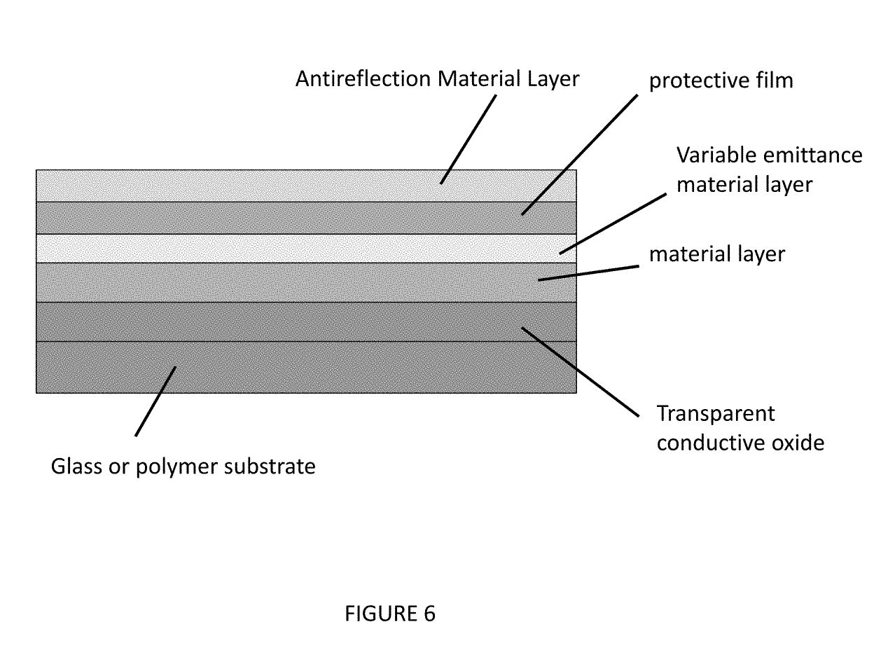

FIG. 7 illustrates a vanadium oxide coating on transparent conducting oxide, for example PVD deposited platinum metal or ALD platinum metal, on a substrate for a smart window.

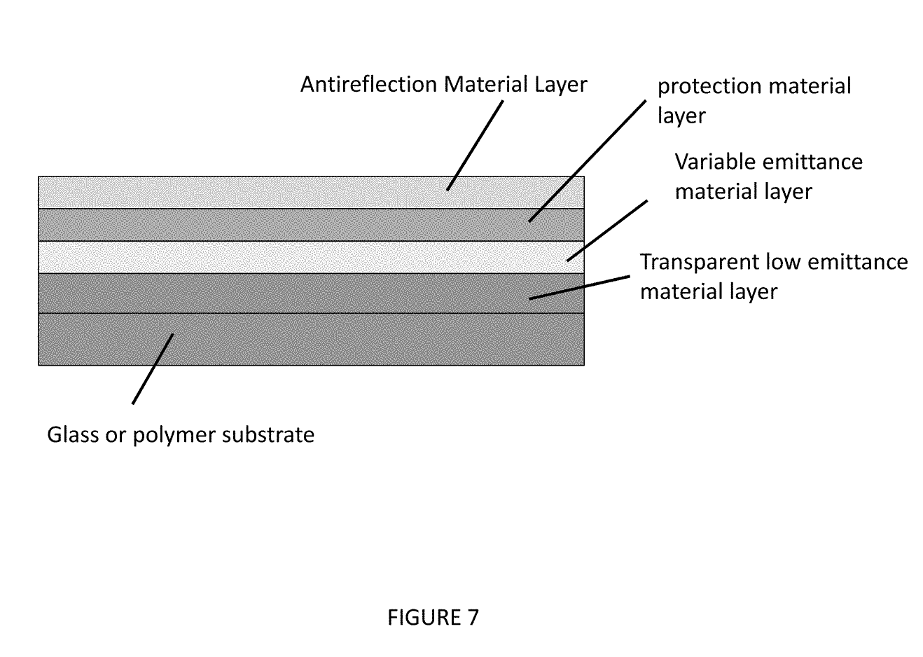

FIG. 8 illustrates a vanadium oxide coating on transparent conducting oxide, for example PVD deposited platinum metal or ALD platinum metal, on a substrate for a smart window.

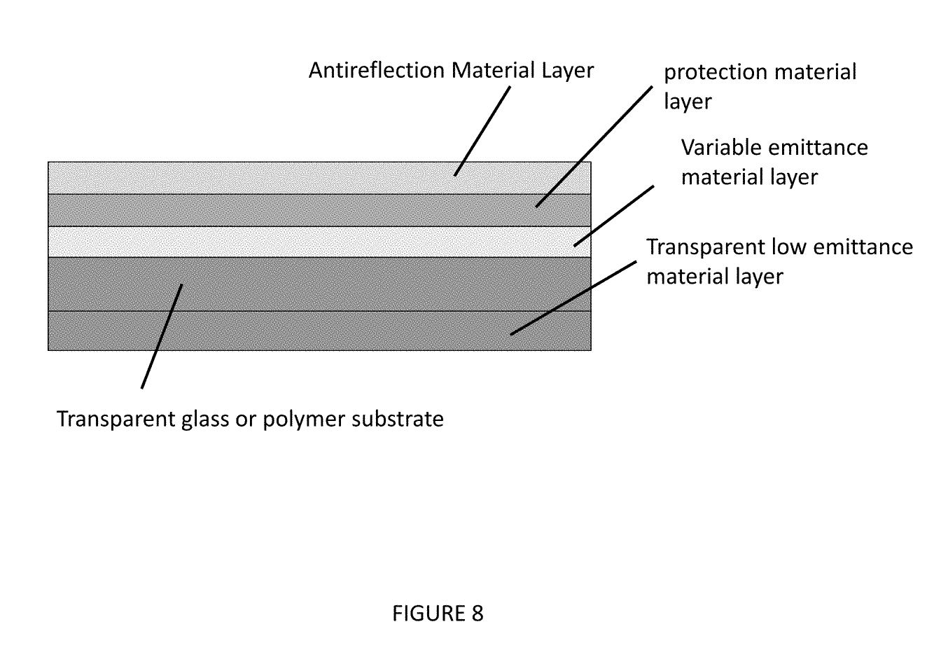

FIG. 9 illustrates a vanadium oxide coating on transparent material layer with selected emittance value that comprise nanoparticles for a smart window.

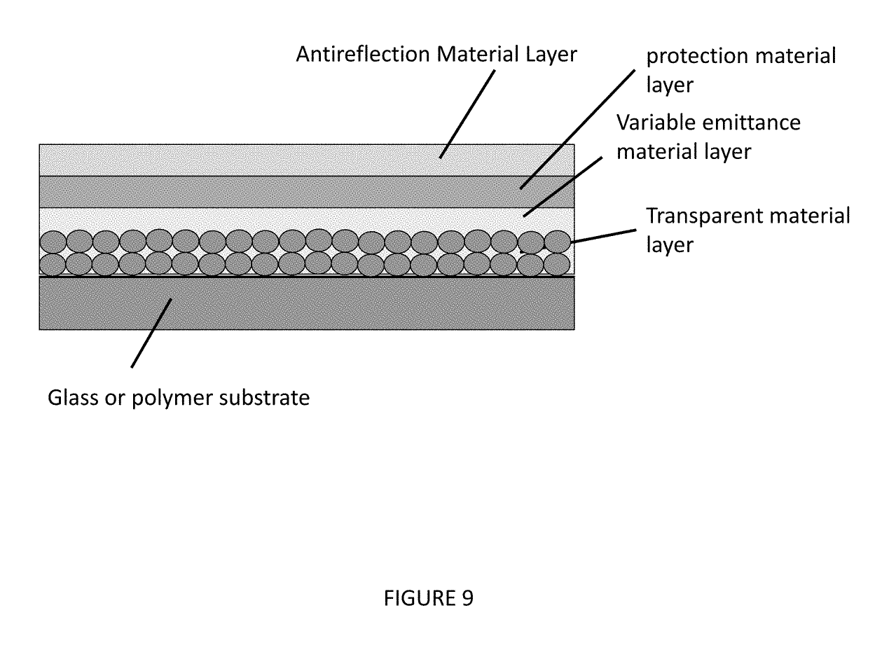

FIG. 10 illustrates a vanadium oxide coating on transparent material layer with selected emittance value that comprise noncontiguous nanoparticles for a smart window.

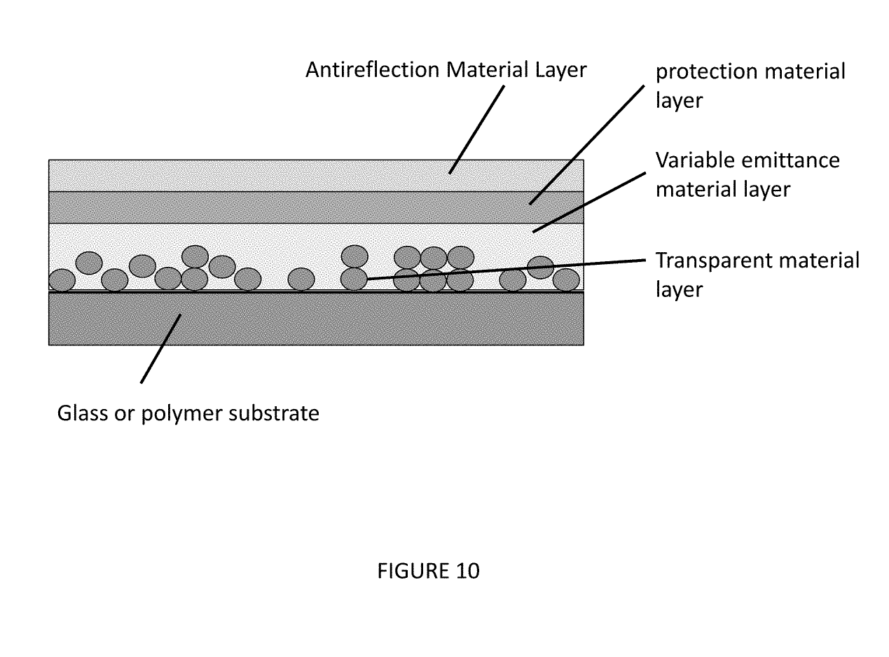

### DETAILED DESCRIPTION

This disclosure describes devices that can use low temperature deposited atomic layer deposition vanadium oxide, deposited at a temperature at about 115° C. or below, and methods of making. For example, devices can be smart window devices or infrared detector devices.

This disclosure describes a window device structure and a method to fabricate a window device structure.

The typically deposition temperature for physical vapor deposited vanadium oxide with significant VO₂ bonding content is 500° C.

As used in the present disclosure, thermochromic material layer means that the material layer has an emittance value that varies with the temperature of the device structure material.

### Example 1

This disclosure describes a window device structure and a method to fabricate a window device structure.

In one embodiment of the window device structure, the window device structure may have a variable emittance characteristic. The window device structure may include a transparent substrate material that may comprise a transparent glass or transparent polymer material. The transparent substrate may be a flexible substrate.

In one embodiment of the present disclosure, the window device structure may contain one or more variable emittance material layer(s) between the first surface of the substrate and the first surface of the window device structure.

The variable emittance characteristic influences the amount of thermal energy radiated into the environment from the outer surface of the window device structure. One aspect of the window device structure is that the emittance varies as a function of the temperature of the variable emittance material layers. One aspect of the window device structure is that the variable emittance material layer(s) may have themochromic characteristics. The emittance of the window device structure is not actively controlled by applying external voltage or current but has a passive control of the variable emittance value.

One aspect of the window device structures is that the window device structure may be a passive smart window device structure. The variable emittance property of the variable emittance material layer may include a lower emittance for a range of higher temperatures and higher emittance for a range of lower temperatures. The variable emittance property of the variable emittance material layer may include a gradual reduction in the emittance values as the temperature is increase from a low temperature to a high temperature. The variable emittance property of the variable emittance material layer may include a range of temperatures, switching temperature (also known as phase transition temperature) where there is a significant change in emittance value.

One aspect of the present disclosure is that the window device structure may be transparent for visible wavelengths.

One aspect of the window device structure is that the emittance is not controlled by an externally applied electric voltage or current and thus the emittance value is passively controlled.

### Substrate

The smart window structure may include a substrate that comprise a glass or polymer material. In some embodiments, the substrate is transparent to visible wavelengths. In some embodiments, the substrate is transparent to infrared wavelengths. In some embodiments, the substrate is transparent to ultraviolet wavelengths. In some embodiments, the glass may be a flexible glass. In some embodiments, the polymer may be a flexible polymer.

Two polymer materials that are advantageous for flexible substrates because of low linear coefficient of thermal expansion, low moisture absorption, large Young's modulus, large tensile strength are Polyethylene terephthalate (PET) and polyethylene naphthalate (PEN), however, PET and PEN have relatively low glass transition temperature and maximum process temperature. PET has a glass transition temperature of about 78° C. and PEN has a glass transition temperature of about 121° C. PET has a maximum process temperature of about 150° C. and PEN has a maximum process temperature of about 200° C. It is advantageous for the deposition process for depositing vanadium oxide material has a process temperature less than 150° C. for PET and a process temperature less than about 200° C. for PEN substrates. The low ALD deposition temperature for depositing vanadium oxide materials is advantageous for the use of PET and PEN flexible substrates. For example, Polyethylene terephthalate (PET) has a linear thermal expansion coefficient of about 15 ppm/° C. and polyethylene naphthalate (PEN) has a linear coefficient of thermal expansion of about 13 ppm/° C. at 300K. Low ALD deposition temperature enables elements on a flexible polymer material substrate with linear coefficient of expansion less than 25 ppm/° C. 1737 glass has a linear coefficient of thermal expansion of about 5 ppm/° C. PET and PEN absorb little water. The moisture absorption percentage for PET and PEN is about 0.14%. PET has a Young's modulus of about 5.3 GPa and PEN has a Young's Modulus of about 6.1 GPa. PET has a tensile strength of about 225 MPa and PEN has a Young's' Modulus of 275 MPa.

A comparison of the properties of PET and PEN compared to other plastic substrates for flexible substrate applications is given in Table 4.1 on page 78 of Flexible Electronics: Materials and Applications (2009) Springer edited by William S. Wong and Alberto Salleo.

| | PET | PEN | PC | PES | PI |
|---|---|---|---|---|---|
| | (Melinex) | (Teonex) | (Lexan) | (Sumilite) | (Kapton) |
| T_{g}, ° C. | 78 | 121 | 150 | 223 | 410 |
| CTE (−55 to 85° C.), ppm/° C. | 15 | 13 | 60-70 | 54 | 30-60 |
| Transmission (400-700 nm), % | 89 | 87 | 90 | 90 | Yellow |
| Moisture absorption, % | 0.14 | 0.14 | 0.4 | 1.4 | 1.8 |
| Young's modulus, Gpa | 5.3 | 6.1 | 1.7 | 2.2 | 2.5 |
| Tensile strength, Mpa | 225 | 275 | — | 83 | 231 |
| Density, gcm⁻³ | 1.4 | 1.36 | 1.2 | 1.37 | 1.43 |
| Refractive index | 1.66 | 1.5-1.75 | 1.58 | 1.66 | — |
| Birefringence, nm | 46 | — | 14 | 13 | — |

### Variable Emittance Material Layer(s)

The variable emittance material layer may comprise compounds of transition metal atoms that may include one or more of vanadium, lanthanum, manganese, titanium, or tungsten. In some embodiments, the transition metal atom is bonded with one or more oxygen atom(s). In some embodiments, the transition metal in the variable emittance material layer is bonded to one or more oxygen atoms to form a metal oxide.

In some embodiments, the variable emittance material layer may comprise a vanadium oxide material layer with VO₂ bonding content within the vanadium oxide material. In some embodiments, the variable emittance material layer may comprise multiple phases of transition metal compound. In some embodiments, the variable emittance material layer may comprise composite of VO₂ phase material, V₂O₅, phase material, V₂O₃, and, V₆O₁₃, and combinations thereof. In some embodiments, the variable emittance material layer comprises a composite for multiple vanadium oxide phases that is designated as VOₓ material.

The vanadium oxide film may comprise crystalline VO₂ material structures. The crystalline VO₂ material structure may comprise crystalline VO₂ grains, nanocrystals, or films. The vanadium oxide film with significant percentage of VO₂ crystalline material structures may have a reversible, temperature-dependent metal-to-insulator (MIT) phase transition temperature having a lower emittance values in the metal state in the insulator state. Vanadium oxide material with significant percentage of crystalline VO₂ bonded material structure may have a metal-to-insulator phase transition temperature of about 68° C. Below the phase transition temperature, the material is insulating and transparent, but above the phase transition temperature, the vanadium oxide film becomes metallic and reflective. A variable emittance layer with a lower emittance value in one state and a higher emittance value in a second state is sometimes known as a two-step variable emittance layer. The metal-to-insulator phase transition temperature can be reduced by doping the variable emittance material layer(s) with dopant atoms that may include, but not be limited to, tungsten or molybdenum atoms.

In some embodiments, low temperature processes such as atomic layer deposition may be used to deposit the variable emittance material layer. In one embodiment, the one or more variable emittance material layer can optionally be an atomic layer deposition (ALD) deposited vanadium oxide material layer that has VO₂ bonding content within the vanadium oxide material. In one embodiment, the one or more variable emittance material layer can be an atomic layer deposition (ALD) deposited vanadium oxide material layer that has VO₂ bonding content within the vanadium oxide material and that comprise dopant atoms such as tungsten atoms have the advantage of modifying the phase transition temperature. In one embodiment, the variable emittance material layer may be deposited using sputtering approach or physical vapor deposition techniques.

The vanadium oxide film may comprise amorphous material. The vanadium oxide film may comprise amorphous material with a high VO₂ bonding content. A vanadium oxide amorphous film with a high VO₂ content may have a gradual change in emittance or resistance value with operation temperature. For certain fabrication process using selected precursor material, a vanadium oxide film deposited by atomic layer deposition at 150° C. is an amorphous material film with a high VO₂ content and has a gradual change in emittance and resistance values with operating temperature.

In some embodiments, the variable emittance layer has a gradual change in emittance values as a function of temperature. In some embodiments, the variable emittance layer has a gradual change in emittance properties and resistance value between 500° K. and 77° K.

### Transparent Low Emittance Material Layer

The window device structure may contain one or more optional transparent low emittance material layer between the second side of the variable emittance layer and the first surface of the substrate such that the transparent low emittance material layer has an emittance value that is lower than the emittance value of the variable emittance material layer(s). The transparent low emittance material layer with selected emittance value can lower the overall emittance value of the smart window structures.

### Transparent Strain Optimizing Material Layer

The window device structure may comprise an optional transparent strain optimizing material layer on the second side of the variable emittance layer that optimizes the strain in the variable emittance material layer. The process of optimizing the strain in the variable emittance material layer may modify the switching temperature (phase transition temperature) of the variable emittance layer. The process of optimizing the strain in the variable emittance material layer may lower the switching temperature (phase transition temperature) to a lower switching temperature (phase transition temperature value). The transparent strain optimizing material layer may also comprise a protection material layer. The protection material layer would provide protection from oxidation and humidity on the second side of the variable emittance layer.

### Protection Material Layer

In an embodiment, a transparent material layer may be deposited on the first surface (first side) of the variable emittance layer to provide protection from oxidation and humidity. In an embodiment, a transparent material layer may be coated on the first surface of the variable emittance layer to provide protection from being etched by acids used in the fabrication process.

### Antireflection Material Layer

The window device structure may include one or more optional antireflection material layer(s) on the first side of the variable emittance layer between the variable emittance layer and the air or vacuum outside environment.

### Hydrophobic Coating Layer

The window device structure may include an optional hydrophobic coating layer on the outer surface that may reduce dust buildup on the window.

Optically Transparent Material Layer(s) with Selected Emittance Value

The smart window material structure may include one or more optical transparent material layer(s) with selected emittance value. The optical transparent material layer (s) will typically be one of the material layers between the glass substrate and the variable emittance material layer.

In some embodiments, the optical transparent material layer(s) may comprise a metal layer, a metal layer with plasmonic properties, a transparent conductive oxide layer, a transparent conductive oxide layer with plasmonic properties, a semiconductor material, a semiconductor material with plasmonic properties, a layer of metal nanowires, a layer of metal nanowires with plasmonic properties, a layer of transparent conductive oxide nanowires, a layer of transparent conductive oxide nanowires with plasmonic properties, a layer of semiconductor nanowires, a layer semiconductor nanowires with plasmonic properties, a layer of metal nanoparticle, a layer of metal nanoparticles with plasmonic properties, a layer of transparent conductive oxide nanoparticle, a layer of transparent conductive oxide nanoparticles with plasmonic properties, a layer of semiconductor nanoparticles, a layer of semiconductor nanoparticles with plasmonic properties.

Optical Transparent Material Layer with Plasmonic Material Properties

The window material structure may include one or more optical transparent material layer(s) with selected emittance value. The optical transparent material layer (s) will typically be one of the material layers between the glass substrate and the variable emittance material layer. In some embodiments, the optical transparent material layer(s) may comprise a metal layer with plasmonic properties, a transparent conductive oxide layer with plasmonic properties, a semiconductor material with plasmonic properties, a layer of metal nanowires with plasmonic properties, a layer of transparent conductive oxide nanowires with plasmonic properties, a layer semiconductor nanowires with plasmonic properties, a layer of metal nanoparticles with plasmonic properties, a layer of transparent conductive oxide nanoparticles with plasmonic properties, or a layer of semiconductor nanoparticles with plasmonic properties.

### Optional Material Layers

The smart window structure may include optional material layer(s) between the substrate and the optically transparent material layer(s) with selected emittance value. The optional material layers may comprise material layers that are designed to be hermetic, improve adhesion, improve nucleation, or accommodate strain differences. In addition, the optional material layers may include transparent low emittance material layer, strain optimizing material layer, variable emittance material layer, oxidation protection material layer, acid protection material layer, anti-reflecting layer, and hydrophobic coating

In some embodiments, the variable emittance material layer is deposited on the first surface of a substrate. The substrate may be a transparent substrate that is optionally flexible. The substrate may comprise a glass, a polymer, or a composite material. An optional protection material layer may be deposited on the first surface of the variable emittance material layer. An optional hydrophobic material layer may be deposited on the optional protection material layer or alternately on the surface of the variable emittance material layer.

In some embodiments, the variable emittance material layer is deposited on the first surface of a substrate. The substrate may be a transparent substrate that is optionally flexible. The substrate may comprise a glass, a polymer, or a composite material. An optional protection material layer may be deposited on the first surface of the variable emittance material layer. An optional antireflection material layer may be deposited on the optional protection material layer or alternately on the surface of the variable emittance material layer.

In some embodiments, the substrate may be a transparent substrate that is optionally flexible. The substrate may comprise a glass, a polymer, or a composite material. An optional transparent strain optimizing material layer to optimize strain in the variable emittance layer to optimize the phase transition temperature of the variable emittance material layer may be deposited on the substrate. The variable emittance material layer may be deposited on the surface of the optional transparent strain optimizing material layer to optimize strain in the variable emittance layer. An optional protection material layer may be deposited on the first surface of the variable emittance material layer. An optional antireflection material layer may be deposited on the optional protection material layer or alternately on the surface of the variable emittance material layer.

In some embodiments, the substrate may be a transparent substrate that is optionally flexible. The substrate may comprise a glass, a polymer, or a composite material. An optional transparent conductive oxide (for example fluorine doped tin oxide, antimony oxide, gallium doped ZnO, or aluminum doped ZnO may be deposited on the substrate. An optional transparent strain optimizing material layer to optimize strain in the variable emittance layer to optimize the phase transition temperature of the variable emittance material layer may be deposited on the optional transparent conductive oxide or the substrate. The variable emittance material layer may be deposited on the surface of the optional transparent strain optimizing material layer to optimize strain in the variable emittance layer. An optional protection material layer may be deposited on the first surface of the variable emittance material layer. An optional antireflection material layer may be deposited on the optional protection material layer or alternately on the surface of the variable emittance material layer.

In some embodiments, the substrate may be a transparent substrate that is optionally flexible. The substrate may comprise a glass, a polymer, or a composite material. A transparent low emittance material layer comprising a metal (for example PVD deposited platinum metal, ALD deposited platinum metal, electroless deposited platinum metal, electroless deposited silver metal, electroless deposited ruthenium metal, ALD deposited silver metal, ALD deposited ruthenium metal, gold nanoparticles, silver nanoparticles, or platinum nanoparticles may be deposited on the substrate. The variable emittance material layer may be deposited on the surface of the transparent low emittance material layer. An optional protection material layer may be deposited on the first surface of the variable emittance material layer. An optional antireflection material layer may be deposited on the optional protection material layer or alternately on the surface of the variable emittance material layer.

In some embodiments, the substrate may be a transparent substrate that is optionally flexible. The substrate may comprise a glass, a polymer, or a composite material. The variable emittance material layer may be deposited on the surface of the substrate or optionally on the surface of a transparent strain optimizing material layer. An optional protection material layer may be deposited on the first surface of the variable emittance material layer. An optional antireflection material layer may be deposited on the optional protection material layer or alternately on the surface of the variable emittance material layer. A transparent low emittance material layer comprising a metal (for example PVD deposited platinum metal, ALD deposited platinum metal, electroless deposited platinum metal, electroless deposited silver metal, electroless deposited ruthenium metal, ALD deposited silver metal, ALD deposited ruthenium metal, gold nanoparticles, silver nanoparticles, or platinum nanoparticles may be deposited on the second surface of the substrate.

### Method

### Example 2

### Etched Copper Foil Substrate Approach

In the Etched Copper Foil Substrate method, the process steps may include:
1. Copper foil substrate.
2. Optionally grow a graphene material layer on the surface of the copper foil substrate. Functionalize the surface of the graphene material layer to improve the adhesion of material layers to the graphene surface. Functionalization approaches include but are not limited to xenon difluoride exposure, low energy nitrogen plasma exposure, and UV ozone exposure. The functionalization approach typically forms sp3 bonds on the surface of the graphene that can facilitate the nucleation of deposited films on the surface of the graphene.
3. Optionally deposit an Antireflection Material Layer (for example deposit a TiO₂ layer).
4. Optionally deposit a protection material layer.
5. Optionally deposit a transparent strain optimizing material layer to optimize strain in thermochromic vanadium oxide film layer to select the phase transition temperature in variable emittance layer.
6. Deposit a variable emittance layer. The variable emittance layer may be a vanadium oxide layer. Crystalline thermochromic vanadium oxide with a two-step metal-to-insulator phase transition characteristic can be obtain by sputter deposition of vanadium oxide at about 500° C. or by atomic layer deposition of vanadium oxide at about 450° C. Alternately, vanadium oxide can be deposited at low temperature and then the vanadium oxide film annealed in a low pressure oxygen ambient at temperature in the range of about 450° C. to about 600° C. to form themochromic vanadium oxide having a metal-insulator phase transition temperature.
7. Optionally, form a transparent low emittance material layer(s) on the surface of the thermochromic vanadium oxide film surface. Several approaches for depositing the transparent low emittance material layer(s) include:
   a. Optionally deposit a transparent conductive oxide, for example fluorine doped tin oxide or antimony oxide, on the surface of the thermochromic vanadium oxide layer.
   b. Optionally, deposit a transparent low emittance material layer comprising a metal, for example PVD deposited platinum metal, ALD platinum metal, ALD silver metal, ALD ruthenium metal, gold nanoparticles, silver nanoparticles, or platinum nanoparticles, on the surface of the thermochromic vanadium oxide layer.
   c. Optionally, deposit a transparent material layer with selected emittance value comprising nanoparticles on the surface of the thermochromic vanadium oxide layer. The nanoparticles may be metal nanoparticles or transparent conductive oxide (TCO) metal oxide nanoparticles. The nanoparticles may have plasmonic properties.
   d. Optionally, deposit a transparent material layer with selected emittance value comprising nanoparticles. The nanoparticles may be metal nanoparticles or transparent conductive oxide (TCO) metal oxide nanoparticles. The nanoparticles may have plasmonic properties
8. Adhere a transparent substrate to the surface of the themochromic vanadium oxide layer. The transparent substrate may be flexible. The transparent substrate may be glass or polymer substrate that is optionally flexible.
9. Etch the copper foil substrate in aqueous ammonium persulfate solution.
10. Optionally deposit transparent low emittance material layer comprising a metal, for example PVD deposited platinum metal, ALD platinum metal, ALD silver metal, ALD ruthenium metal, gold nanoparticles, silver nanoparticles, or platinum nanoparticles, on the exposed surface of the transparent substrate.
11. Optionally deposit a protection material layer if the protection material was not deposited in step 4.
12. Optionally deposit an Antireflection Material Layer (for example deposit a TiO₂ layer) if the Antireflection Material Layer was not deposited in step 3.
13. Optionally deposit a hydrophobic material layer on the surface of the optional antireflection layer, protection layer, or variable emittance layer.

### Example 3

### Adhere Transparent Substrate and Peel

In the Adhere Transparent Substrate and Peel method, the process steps may include:
1. Copper foil substrate (copper is a transition metal).
2. Grow a graphene material layer on the surface of the copper foil substrate.
3. Functionalize the surface of graphene material layer to improve the adhesion of material layers to the graphene surface. Functionalization approaches include but are not limited to xenon difluoride exposure, low energy nitrogen plasma exposure, or UV ozone exposure. The functionalization approach typically forms sp3 bonds on the surface of the graphene that can facilitate the nucleation of deposited films on the surface of the graphene.
4. Optionally deposit an Antireflection Material Layer (for example deposit a TiO₂ layer).
5. Optionally deposit a protection material layer.
6. Optionally deposit a transparent strain optimizing material layer to optimize strain in thermochromic vanadium oxide film layer to select the phase transition temperature in variable emittance layer.
7. Deposit a variable emittance layer. The variable emittance layer may be a vanadium oxide layer. Crystalline thermochromic vanadium oxide with a two-step metal-to-insulator phase transition (or sharp or abrupt metal insulator transition) temperature characteristic obtained by sputter deposition of vanadium oxide at about 500° C. or by atomic layer deposition of vanadium oxide at about 450° C. Alternately, vanadium oxide can be deposited at low temperature and then the vanadium oxide film annealed in a low oxygen pressure ambient at temperature in the range of about 450° C. to about 600° C. to form themochromic vanadium oxide having a metal-insulator phase transition temperature characteristics.
8. Optionally, form a transparent low emittance material layer(s) on the surface of the thermochromic vanadium oxide film surface. Several approaches for depositing the transparent low emittance material layer(s) include:
   a. Optionally deposit a transparent conductive oxide (for example fluorine doped tin oxide or antimony oxide) on the surface of the thermochromic vanadium oxide layer.
   b. Optionally, deposit a transparent low emittance material layer comprising a metal (for example PVD deposited platinum metal, ALD platinum metal, ALD silver metal, ALD ruthenium metal, gold nanoparticles, silver nanoparticles, or platinum nanoparticles) on the surface of the thermochromic vanadium oxide layer.
   c. Optionally, deposit a transparent material layer with selected emittance value comprising nanoparticles on the surface of the thermochromic vanadium oxide layer. The nanoparticles may be metal nanoparticles or transparent conductive oxide (TCO) metal oxide nanoparticles. The nanoparticles may have plasmonic properties.
   d. Optionally, deposit a transparent material layer with selected emittance value comprising nanoparticles. The nanoparticles may be metal nanoparticles or transparent conductive oxide (TCO) metal oxide nanoparticles. The nanoparticles may have plasmonic properties
9. Adhere a first flexible transparent substrate to the surface of the themochromic vanadium oxide layer. The first flexible transparent substrate may be glass or polymer substrate.
10. Peel the first flexible transparent substrate, the attached material layers, and the graphene material layer from the surface of the copper.
11. Optionally adhere a second transparent substrate to the surface of the first flexible transparent substrate. The second transparent substrate may provide mechanical support to the smart window material layers. The second transparent substrate may be a flexible substrate. The second transparent substrate may be a nonflexible substrate. The second transparent substrate may be polymer or a glass material. The second transparent substrate may be adhered to the exposed surface of the first flexible transparent substrate or the second transparent substrate may be adhered to the exposed graphene surface of the smart window material layers.

### Example 3

### Transfer of Film Layers to Transparent Substrate

In the Transfer of Film Layer to Transparent Substrate method, process steps may include:
1. Copper foil substrate (copper is a transition metal).
2. Grow a graphene material layer on the surface of copper.
3. Functionalize the surface of graphene material layer to improve the adhesion of material layers to the graphene surface. Functionalization approaches include but are not limited to xenon difluoride exposure, low energy nitrogen plasma exposure, or UV ozone exposure. The functionalization approach typically forms sp3 bonds on the surface of the graphene that can facilitate the nucleation of deposited films on the surface of the graphene.
4. Optionally, form an optical transparent material layer(s) on the surface of the thermochromic vanadium oxide film surface. Several approaches for depositing the optical transparent material layer(s) include:
   a. Optionally deposit a transparent conductive oxide (for example fluorine doped tin oxide or antimony oxide) on the surface of the thermochromic vanadium oxide layer.
   b. Optionally, deposit a transparent low emittance material layer comprising a metal (for example PVD deposited platinum metal, ALD platinum metal, ALD silver metal, ALD ruthenium metal, gold nanoparticles, silver nanoparticles, or platinum nanoparticles) on the surface of the thermochromic vanadium oxide layer.
   c. Optionally, deposit a transparent material layer with selected emittance value comprising nanoparticles on the surface of the thermochromic vanadium oxide layer. The nanoparticles may be metal nanoparticles or transparent conductive oxide (TCO) metal oxide nanoparticles. The nanoparticles may have plasmonic properties.
   d. Optionally, deposit a transparent material layer with selected emittance value comprising nanoparticles. The nanoparticles may be metal nanoparticles or transparent conductive oxide (TCO) metal oxide nanoparticles. The nanoparticles may have plasmonic properties
5. Optionally deposit a transparent strain optimizing material layer to optimize strain in thermochromic vanadium oxide film layer to select the phase transition temperature in the variable emittance layer.
6. Deposit a variable emittance layer. The variable emittance layer may be a vanadium oxide layer. Crystalline thermochromic variable emittance film with a metal-insulator phase transition temperature at a selected temperature can be obtained by laser anneal of the variable emittance film. For example, crystalline thermochromic vanadium oxide film with a metal-insulator phase transition at a selected phase transition temperature can be obtained via laser anneal of the vanadium oxide film.
7. Optionally deposit a protection material layer.
8. Optionally deposit an Antireflection Material Layer (for example deposit a TiO₂ layer).
9. Optionally deposit a hydrophobic material layer on surface of optional antireflection layer, protection layer, or variable emittance layer.
10. Peel the material films and graphene layer from the surface of the copper and transfer to the transparent substrate. The transparent substrate may have a transparent adhesive on the surface to facilitate the transfer of the material films and graphene layer. The transparent substrate may be flexible. The transparent substrate may be glass or polymer substrate that is optionally flexible.
11. Optionally deposit a protection material layer if the protection material was not deposited in step 7.
12. Optionally deposit an Antireflection Material Layer (for example deposit a TiO₂ layer) if the Antireflection Material Layer was not deposited in step 8.
13. Optionally deposit a hydrophobic material layer on surface of optional antireflection layer, protection layer, or variable emittance layer if the hydrophobic layer was not deposited in step 9.
14. Optionally deposit transparent low emittance material layer comprising a metal (for example PVD deposited platinum metal, ALD platinum metal, ALD silver metal, ALD ruthenium metal, gold nanoparticles, silver nanoparticles, platinum nanoparticles) on the exposed surface of the transparent substrate.

### Example 5

### Laser Anneal of Variable Emittance Thermochromic Film

In the Laser Anneal of Variable Emittance Thermochromic Film method, the process steps may include:
1. Transparent substrate. The transparent substrate may be flexible. The transparent substrate may be glass or polymer substrate that is optionally flexible.
2. Optionally, form an optical transparent material layer(s) on the surface of the thermochromic vanadium oxide film surface. Several approach for depositing the optical transparent material layer(s) include:
   a. Optionally deposit a transparent conductive oxide (for example fluorine doped tin oxide or antimony oxide) on the surface of the thermochromic vanadium oxide layer.
   b. Optionally, deposit a transparent low emittance material layer comprising a metal (for example PVD deposited platinum metal, ALD platinum metal, ALD silver metal, ALD ruthenium metal, gold nanoparticles, silver nanoparticles, platinum nanoparticles) on the surface of the thermochromic vanadium oxide layer.
   c. Optionally, deposit a transparent material layer with selected emittance value comprising nanoparticles on the surface of the thermochromic vanadium oxide layer. The nanoparticles may be metal nanoparticles or transparent conductive oxide (TCO) metal oxide nanoparticles. The nanoparticles may have plasmonic properties.
   d. Optionally, deposit a transparent material layer with selected emittance value comprising nanoparticles. The nanoparticles may be metal nanoparticles or transparent conductive oxide (TCO) metal oxide nanoparticles. The nanoparticles may have plasmonic properties
3. Optionally deposit a transparent strain optimizing material layer to optimize strain in thermochromic vanadium oxide film layer to select the phase transition temperature in variable emittance layer.
4. Deposit a variable emittance layer. The variable emittance layer may be a vanadium oxide layer. Crystalline thermochromic variable emittance film with a metal-insulator transition at a selected phase transition temperature can be obtained by laser anneal of the variable emittance film. For example, crystalline thermochromic vanadium oxide film with a metal-insulator transition at a selected phase transition temperature can be obtained laser anneal of the vanadium oxide film.
5. Optionally deposit a protection material layer.
6. Optionally deposit an Antireflection Material Layer (for example deposit a TiO₂ layer).
7. Optionally deposit a hydrophobic material layer on surface of optional antireflection layer, protection layer, or variable emittance layer.
8. Optionally deposit transparent low emittance material layer comprising a metal (for example PVD deposited platinum metal, ALD platinum metal, ALD silver metal, ALD ruthenium metal, gold nanoparticles, silver nanoparticles, platinum nanoparticles) on the exposed surface of the transparent substrate.

The method to fabricate the smart window structure may include low temperature processes.

The low temperature processes may comprise atomic layer deposition to deposit the variable emittance material layer, atomic layer deposition to deposit the optical transparent material layer with selected emittance value, atomic layer deposition to deposit the transparent strain optimizing material layer, atomic layer deposition of the optical transparent material layer with selected emittance, physical vapor deposition of the optical transparent material layer with selected emittance value, laser annealing of one or more of the material layers, rapid thermal annealing of one or more of the material layers, or deposition of nanoparticles to form the optical transparent material layer with selected emittance value. The variable emittance layer as deposited by atomic layer deposition or physical vapor deposition can have a gradual change emittance value with temperature. Annealing can convert an atomic layer deposition or physical vapor deposited variable emittance layer into a crystalline, polycrystalline, of nanocrystalline material that has a two-step metal-to-insulator transition with a lower emittance value in one state and a higher emittance value with a gradual transition in emittance value between the two states. A typical annealing condition to achieve a two-step vanadium oxide variable emittance layer is annealing in a low oxygen pressure ambient at temperature in the range of about 450° C. to about 600° C. The laser anneal of the variable emittance layer can crystallize the variable emittance layer into a crystalline, polycrystalline, of nanocrystalline material that has a two-step metal-to-insulator transition. The laser anneal deposits heat primarily into the variable emittance material layer and does not increase the temperature of the substrate. Thus, laser annealing of the variable emittance layer is compatible with a two-step metal-to-insulator variable emittance layer on a flexible polymer substrate. One advantage of low process temperature is that variable on a flexible polymer substrate or a flexible glass substrate.

The transparent low emittance material layer, transparent strain optimizing material layer, variable emittance material layer, oxidation protection material layer, acid protection material layer, anti-reflecting layer, and optional hydrophobic coating layer may be deposited in the same ALD growth system

The method to fabricate the smart window structure may include low temperature processes. The low temperature processes may comprise atomic layer deposition (ALD) to deposit the variable emittance material layer, atomic layer deposition to deposit the optical transparent material layer with selected emittance value, laser annealing, rapid thermal annealing, or deposition of nanoparticles to form the optical transparent material layer with selected emittance value.

The ALD growth system may be a roll-to-roll growth system.

In some embodiments, an optional anneal process may be used to optimize the properties of the variable emittance material. In one embodiment, the optional anneal process may increase the VO₂ bonding content in the variable emittance material layer. In one embodiment, an optional anneal process may be used to increase the VO₂ bonding content within the vanadium oxide material. In one embodiment, an optional laser anneal process may be used to optimize the properties of the variable emittance material layer. In one embodiment, the optional laser anneal process may increase the VO₂ bonding content in the variable emittance material layer. In one embodiment, the optional laser anneal may convert an amorphous film to a crystalline film, a polycrystalline film, or a nanocrystalline film. In one embodiment, an optional rapid thermal anneal process may be used to optimize the properties of the variable emittance material layer. In one embodiment, the optional rapid thermal anneal process may increase the VO₂ bonding content in the variable emittance material layer.

In some embodiments, the variable emittance material layer is grown by atomic layer deposition.

In one example, vanadium oxide films were deposited by atomic layer deposition (ALD) at 150° C. using tetrakis(ethylmethyl)amido vanadium (TEMAV, Air Liquide Electronics) and ozone precursors with film thicknesses ranging from 7-34 nm. This particular vanadium precursor may help facilitate the preferential formation of VO₂ since it is already in the 4+ oxidation state. Optimized pulse and purge sequences resulted in a growth rate of 0.7-0.9 Å/cycle, consistent with previous reports. X-ray photoelectron spectroscopy was performed to determine the quality, stoichiometry, and depth uniformity of the amorphous films. All films exhibited adventitious carbon contamination on the surface of the films due to atmospheric transfer from the ALD chamber. In addition, the top ˜1 nm of the film exhibited two V2p peaks at 517.7 and 516.3 eV correlating to V₂O₅ and VO₂ components of the film, respectively. However after removing the top surface, no residual carbon contamination was detected and the films had only a single VO₂ peak. The full-width-at-half-max of the single VO₂ peak ranged from 2-2.7 eV, which is smaller than typically seen for VO₂ films, and is indicative of the high uniformity and quality of these films. By depth profiling through the film, a shoulder on the low binding energy side of the V2p peak (513.5 eV) was revealed near the VOₓ/Si interface, suggesting that the initial film is highly oxygen deficient.

Electrical performance of these amorphous films, on both sapphire and SiO2/Si insulating substrates, was assessed from 77-500K. The deposited amorphous vanadium oxide films showed an exponential change in resistance of ten orders of magnitude over the entire temperature range from 77K to 500K. This data results in an average activation energy of −0.20 eV and temperature coefficient of resistance of 2.39% at 310K. This shows the potential to use amorphous vanadium oxide films, which are not as structurally ordered, to induce more gradually electrical and optical changes.

While the above description provides example embodiments, it will be appreciated that the present invention is susceptible to modification and change without departing from the fair meaning and scope of the accompanying claims. Accordingly, what has been described is merely illustrative of the application of aspects of embodiments of the invention and numerous modifications and variations of the present invention are possible in light of the above teachings.

An advantage is that the ALD vanadium oxide film can be deposited at low temperatures The ALD vanadium oxide film can be deposited at a temperature as low as 115° C. The low deposition temperature capability enables the ALD vanadium oxide film to be deposited on polymer substrate material. The low deposition temperature is advantageous to enable the deposition on a greater number of polymer material types then would be possible for higher deposition temperature approach. The low deposition temperature of the ALD vanadium oxide film deposition is advantageous to enable the deposition on a greater number of glass material type then would be possible for a higher deposition temperature deposition approach. The polymer substrate material or the glass substrate material can be flexible.

An advantage is that transparent low emittance material layer, transparent strain optimizing material layer, variable emittance material layer, oxidation protection material layer, acid protection material layer, anti-reflecting layer, and optional hydrophobic coating layer may be deposited in the same ALD growth system.

An advantage is that the ALD process is a very uniform deposition, has repeatable emittance properties, and is pinhole free.

An advantage is that the ALD process can be a manufacturable process and can be implemented using role to role processing.

An advantage is that the ALD process is economical because the ALD process uses small amounts of precursor material.

The ALD vanadium oxide film can be deposited at low temperatures The ALD vanadium oxide film can be deposited at as low as 115° C. The low deposition temperature capability enables the ALD vanadium oxide film to be deposited on polymer material. The low deposition temperature of the ALD vanadium oxide film deposition is advantageous to enable the deposition on a greater number of glass material type then would be possible for a higher deposition temperature deposition approach.

The ALD vanadium oxide film can be deposited on three-dimensional surfaces. The ability to deposit on three dimensional surface enable a larger effective thickness of the vanadium oxide material for increasing infrared electromagnetic absorption for infrared sensing applications or a larger effective thickness for increasing terahertz electromagnetic absorption for terahertz absorption

The ALD vanadium oxide film offers advantages in a variety of applications including electrochemical applications, energy storage and conversion processes, thermoelectric devices, Mott transistors, and smart windows. Integrating solar cells that can efficiently harness and store solar energy into windows that require the material to be transparent has remained challenging.

Many modifications and variations of the present invention are possible in light of the above teachings. It is therefore to be understood that the claimed invention may be practiced otherwise than as specifically described. Any reference to claim elements in the singular, e.g., using the articles “a,” “an,” “the,” or “said” is not construed as limiting the element to the singular.

What we claim is:

1. A method of making a variable emittance window comprising:
providing a transparent substrate;
applying a transparent low emittance material layer to the substrate;
applying a variable emittance material layer onto the transparent low emittance material layer;
applying a protection material layer onto the variable emittance material layer; and
applying an antireflection material layer onto the protection material layer.

2. The method of making a variable emittance window of claim 1 further including the step of:
annealing to form a variable emittance layer.

3. The method of making a variable emittance window of claim 2 wherein the annealing is laser annealing.

4. A method of making a variable emittance window comprising:
providing a metal foil substrate;
applying an antireflection material layer onto the metal foil substrate;
applying a protection material layer onto the antireflection material layer;
applying a variable emittance material layer onto the protection material layer;
annealing to form a two-step variable emittance layer;
applying a transparent low emittance material layer to the two-step variable emittance layer;
adhering a transparent substrate to the transparent low emittance material layer; and
removing the metal foil substrate.

5. A method of making a variable emittance window comprising:
providing a transition metal foil substrate;
growing a graphene material layer on the metal foil substrate;
functionalizing the surface of the graphene material layer;
applying an antireflection material layer onto the metal foil substrate;
applying a protection material layer onto the antireflection material layer;
applying a variable emittance material layer onto the protection material layer;
annealing to form a two-step variable emittance layer;
applying a transparent low emittance material layer to the two-step variable emittance layer;
applying a first flexible transparent substrate to the transparent low emittance material layer; and
peeling the first flexible transparent substrate, the transparent low emittance material layer, the two-step variable emittance layer, the protection material layer, the antireflection material layer, and the functionalized graphene material layer from the surface of the copper.

6. The method of making the variable emittance window of claim 5, wherein a second transparent substrate is adhered to the exposed surface of the first flexible transparent substrate or to the graphene material layer.

7. The method of making the variable emittance window of claim 5 wherein the step of applying a variable emittance material layer comprises an atomic layer deposition process and wherein the step of applying occurs at a temperature at or below 115° C.

8. A method of making a variable emittance window comprising:
providing a transition metal foil substrate;
growing a graphene material layer on the transition metal foil substrate;
functionalizing a surface of the graphene material layer;
applying a transparent low emittance material layer to the graphene material layer;
applying a variable emittance material layer onto the transparent low emittance material layer;
annealing to form a two-step variable emittance film;
applying a protection material layer onto the variable emittance material film; and
applying an antireflection material layer onto the protection material layer.
adhering a polymer tape onto the antireflection material layer;
peeling the polymer tape, the antireflection material layer, the protection material layer, the variable emittance material layer, the transparent low emittance material layer, and the graphene material layer from the surface of the metal foil substrate and transferring to a transparent substrate; and
releasing the polymer tape.
